(19) United States
(12) Patent Application Publication
(10) Pub. No.: US 2026/0182187 A1
(43) Pub. Date: Jun. 25, 2026

(54) DISPLAY PANEL, METHOD FOR MANUFACTURING THE SAME, AND DISPLAY APPARATUS

(71) Applicant: Xiamen Tianma Display Technology Co., Ltd., Xiamen (CN)

(72) Inventors: Shui HE, Xiamen (CN); Ying WANG, Xiamen (CN); Liling LIN, Xiamen (CN)

(73) Assignee: Xiamen Tianma Display Technology Co., Ltd., Xiamen (CN)

(21) Appl. No.: 19/417,248

(22) Filed: Dec. 11, 2025

(30) Foreign Application Priority Data
Dec. 23, 2024 (CN) 202411906871.X

(51) Int. Cl. H10K 59/131; H10K 59/12; H10K 59/80

(52) U.S. Cl. CPC H10K 59/131; H10K 59/1201; H10K 59/873

(57) ABSTRACT

Embodiments of the present application provide a display panel, a method for manufacturing the display panel, and a display apparatus. The display panel includes a substrate and a first metal wire located on a side of the substrate, the first metal wire comprises a first layer, a second layer, and a third layer stacked together; the second layer comprises a main body and a protective portion, the protective portion comprises a metal compound and covers at least a part of sidewalls of the main body along a first direction; the first direction is parallel to a plane where the display panel is located and extends from the main body toward the protective portion. The corrosion-resistant property of the metal compound is utilized to protect the sidewalls of the main body in the present application, which is conducive to improving the structural stability and the conductivity of the first metal wire.

### CROSS-REFERENCE TO RELATED APPLICATIONS

The present application claims priority to Chinese Patent Application No. 202411906871.X, titled “DISPLAY PANEL, METHOD FOR MANUFACTURING THE SAME, AND DISPLAY APPARATUS” and filed on Dec. 23, 2024, which is hereby incorporated by reference in its entirety.

### TECHNICAL FIELD

The present application relates to the technical field of display, and in particular to a display panel, method for manufacturing the same, and display apparatus.

### BACKGROUND

In existing display panels, electrical signal traces are typically configured as laminated metal structures. Due to manufacturing processes and location limitations of electrical signal traces, some electrical signal traces in display panels are prone to corrosion, affecting the performance and structural stability of these electrical signal traces. Therefore, a solution is urgently needed.

### SUMMARY

In a first aspect, embodiments of the present application provide a display panel comprising a substrate and a first metal wire located on a side of the substrate, the first metal wire comprising a first layer, a second layer, and a third layer that are stacked, the second layer being located between the first layer and the third layer; the second layer comprises a main body and a protective portion, the protective portion comprising a metal compound and covering at least a part of sidewalls of the main body along a first direction, wherein the first direction is parallel to a plane where the display panel is located and extends from the main body toward the protective portion.

In a second aspect, embodiments of the present application provide a method for manufacturing the display panel, configured to manufacture the display panel provided in the first aspect, the method comprising: providing the substrate; stacking and manufacturing a first metal layer, a second metal layer, and a third metal layer on the side of the substrate to form the third layer, an initial second layer, and the first layer of the first metal wire, respectively; and injecting a gas into sidewalls of the initial second layer, the gas reacts with a metal in the second metal layer to form a metal compound, thereby forming the second layer.

In a third aspect, embodiments of the present application provide a display apparatus comprising a display panel. The display panel comprises a substrate and a first metal wire located on a side of the substrate, the first metal wire comprises a first layer, a second layer, and a third layer that are stacked, and the second layer being located between the first layer and the third layer; the second layer comprises a main body and a protective portion, and the protective portion comprises a metal compound and covering at least a part of sidewalls of the main body along a first direction, wherein the first direction is parallel to a plane where the display panel is located and extends from the main body toward the protective portion.

### BRIEF DESCRIPTION OF THE DRAWINGS

To more clearly illustrate the technical solutions of the embodiments of the present application, the drawings required for use in the embodiments will be introduced in detail below, apparently, the drawings described below represent only some embodiments of the present application. Those skilled in the art can derive other drawings based on these drawings without inventive effort.

FIG. 1 is a schematic structural diagram of a display panel provided in an embodiment of the present application;

FIG. 2 is a schematic structural diagram of another display panel provided in an embodiment of the present application;

FIG. 3 is a schematic structural diagram of another display panel provided in an embodiment of the present application;

FIG. 4 is a schematic structural diagram of another display panel provided in an embodiment of the present application;

FIG. 5 is a plan view of a display panel provided in an embodiment of the present application;

FIG. 6 is a schematic structural diagram of the display panel shown in FIG. 5;

FIG. 7 is a schematic structural diagram of another display panel provided in an embodiment of the present application;

FIG. 8 is a schematic structural diagram of another display panel provided in an embodiment of the present application;

FIG. 9 is a schematic structural diagram of another display panel provided in an embodiment of the present application;

FIG. 10 is a flowchart of a manufacturing process for a display panel provided in an embodiment of the present application;

FIG. 11 is a flowchart of a manufacturing process for another display panel provided in an embodiment of the present application; and

FIG. 12 is a schematic diagram of a display apparatus provided in an embodiment of the present application.

### DETAILED DESCRIPTION

To better understand the technical solutions of the present application, the following embodiments of the present application are described in detail with reference to the drawings.

It should be understood that the embodiments described are only some of the embodiments of the present application, rather than all of embodiments. Based on the embodiments of the present application, all other embodiments derived by those skilled in the art without inventive effort are within the scope of protection in the present application.

The terms used in the embodiments of the present application are intended solely to describe specific embodiments and are not intended to limit the present application. The singular forms “a,” “the,” and “this” used in the embodiments of the present application and the appended claims are intended to include the plural forms, unless the context clearly indicates otherwise.

It should be understood that the term “and/or” as used herein is merely a description of an association between related objects, indicating that three possible relationships exist. For example, “A and/or B” can mean: A exists alone, A and B exist simultaneously, or B exists alone. Furthermore, the character “/” in the present application generally indicates an “or” relationship between the associated objects.

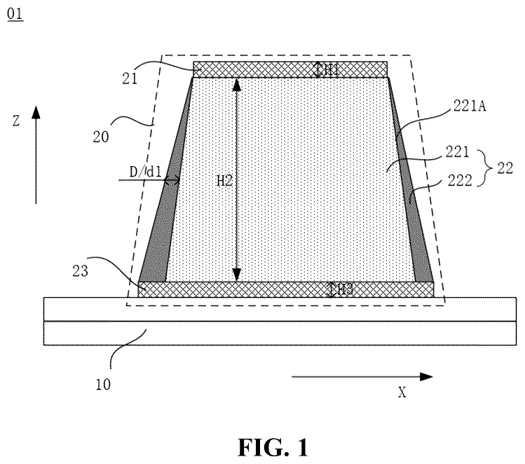

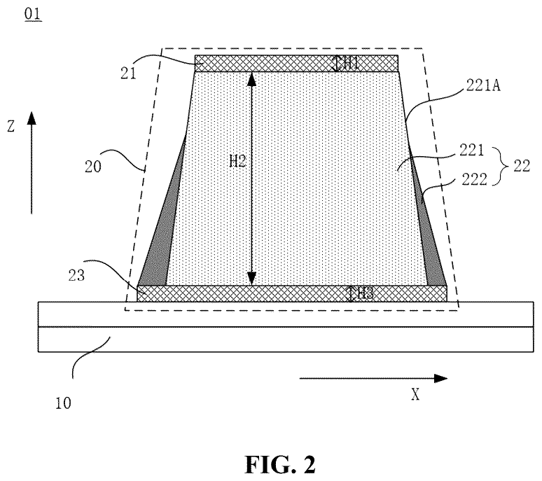

FIG. 1 is a schematic structural diagram of a display panel provided in an embodiment of the present application, and FIG. 2 is a schematic structural diagram of another display panel provided in an embodiment of the present application.

Some embodiments of the present application provide a display panel 01. As shown in FIGS. 1 and 2, the display panel 01 includes a substrate 10 and a first metal wire 20 located on one side of the substrate 10. The first metal wire 20 can be configured to transmit electrical signals. The first metal wire 20 includes a first layer 21, a second layer 22, and a third layer 23 that are stacked. The second layer 22 is located between the first layer 21 and the third layer 23.

Exemplarily, as shown in FIGS. 1 and 2, the first layer 21 is located at the side of the third layer 23 away from the substrate 10. That is, in a direction Z perpendicular to the plane where the display panel 01 is located, the third layer 23, the second layer 22, and the first layer 21 can be arranged in sequence.

Exemplarily, as shown in FIGS. 1 and 2, a thickness H2 of the second layer 22 is greater than a thickness H1 of the first layer 21, and is also greater than a thickness H3 of the third layer 23.

The second layer 22 includes a main body 221 and a protective portion 222. The protective portion 222 contains a metal compound. Along a first direction X, the protective portion 222 covers at least a part of the sidewalls 221A of the main body 221. The first direction X is parallel to the plane where the display panel 01 is located and extends from the main body 221 toward the protective portion 222.

That is, along the first direction X, at least a part of the sidewalls 221A of the main body 221 are covered by the protective portion 222 containing the metal compound.

Optionally, as shown in FIG. 1, in the first direction X, the protective portion 222 covers all of the sidewalls 221A of the main body 221.

Optionally, as shown in FIG. 2, in the first direction X, the protective portion 222 covers only a part of the sidewalls 221A of the main body 221.

It is understood that metal compounds generally have certain corrosion-resistant property, and certain specific metal compounds, in particular, have exceptionally excellent oxidation and corrosion resistance.

The inventors of the present application have discovered through research that the second layer of a first metal wire is typically used as the primary material for transmitting electrical signals, and the performance of the second layer often determines the conductivity of the first metal wire. However, in the prior art, the sidewalls of the second layer are not protected by a protective layer, which is easily lead to the etching solution used in the display panel manufacturing process and/or corrosive ions present in the display panel invading the second layer through the sidewalls of the second layer, corroding the metal in the second layer and affecting the conductivity and structural stability of the first metal wire.

In view of this, in the embodiments of the present application, a protective portion 222 containing a metal compound is provided to cover at least a part of the sidewalls 221A of the main body 221 in the second layer 22, the corrosion-resistant property of the metal compound can be utilized to protect the sidewalls 221A of the main body 221, thereby reducing the erosion of the main body 221 by corrosive materials from the side surfaces of the second layer 22, which is conducive to improving the structural stability and conductivity of the first metal wire 20.

Optionally, as shown in FIG. 1, the protective portion 222 is located outside the main body 221 and is in contact with the sidewalls 221A of the main body 221. That is, the second layer 22 may include an inner layer and an outer layer, with the main body 221 located in the inner layer and the protective portion 222 located in the outer layer.

Since the protective portion 222 contains a metal compound, the protective portion 222 is in contact with the sidewalls 221A of the main body 221. During the manufacturing process of the second layer 22, the protective portion 222 can be formed by injecting gas into the metal in the second layer 22, eliminating the need for manufacturing an additional layer of protective material on the side surfaces of the second layer 22, which is conducive to simplifying the manufacturing process for the protective portion 222 and reducing the manufacturing cost of the first metal wire 20.

Optionally, the protective portion 222 includes at least one of a metal nitride or a metal fluoride. During the manufacturing process of the second layer 22, nitrogen-containing gas or fluorine-containing gas can be injected into the metal in the second layer 22, allowing the nitrogen ions and fluoride ions to react with the metal in the second layer 22 to form the protective portion 222.

Exemplarily, in the second layer 22, the main body 221 includes aluminum, and the protective portion 222 includes at least one of aluminum nitride or aluminum fluoride.

Since aluminum has excellent conductivity and is economical, the main body 221 is constructed of aluminum, ensuring good conductivity for the first metal wire 20 while reducing costs. Aluminum nitride and aluminum fluoride both have high chemical stability and are resistant to high temperatures and acid and alkali corrosion. The protective portion 222 is constructed of at least one of aluminum nitride or aluminum fluoride, which is conducive to enhancing its ability to isolate corrosive materials, thereby enhancing its ability to protect the main body 221.

During the manufacturing process of the second layer 22, nitrogen (N₂) or a fluorine-containing gas can be injected into the side surfaces of the second layer 22. The nitrogen reacts with the aluminum metal (Al) on the side surfaces of the second layer 22 to form aluminum nitride, according to the chemical reaction formula: 2AL+N₂→2AlN. Fluoride ions (F⁻) react with the aluminum metal (Al) on the side surfaces of the second layer 22 to form aluminum fluoride, according to the chemical reaction formula: AL+F⁻→ALF₃.

Exemplarily, the fluorine-containing gas can be carbon tetrafluoride, sulfur hexafluoride, or other gases.

Referring to FIG. 1, in an embodiment of the present application, the protective portion 222 covers the sidewalls 221A of the main body 221 along the first direction X. In this way, the protective portion 222 can completely cover the sidewalls 221A of the main body 221, which is conducive to achieving full protection of the sidewalls 221A of the main body 221, and is conducive to improving the corrosion protection of the first metal wire 20, thereby ensuring the structural stability and electrical conductivity of the first metal wire 20.

Furthermore, full protection of the sidewalls 221A of the main body 221 is conducive to preventing relatively deep grooves from forming on the side surfaces of the second layer 22, and, when subsequent film layers are manufactured on the first metal wire 20, to preventing the breakage of the subsequent film layers caused by failure to adhere to the side surfaces of the second layer 22.

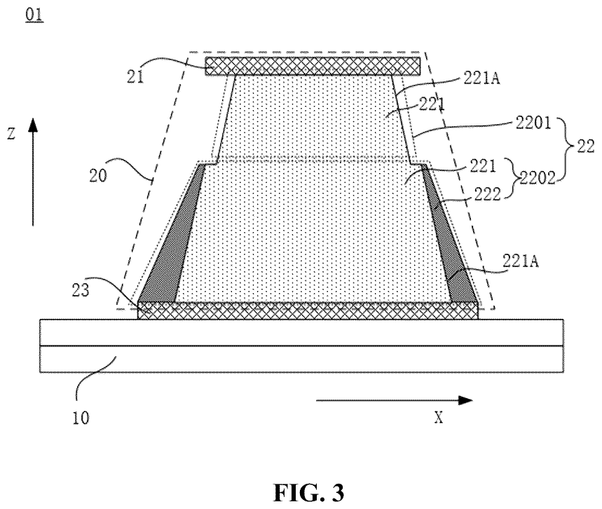

FIG. 3 is a schematic structural diagram of another display panel provided in an embodiment of the present application.

In an embodiment of the present application, as shown in FIG. 3, the second layer 22 includes a first sub-layer 2201 and a second sub-layer 2202. The first sub-layer 2201 and the second sub-layer 2202 are connected in a direction Z perpendicular to the plane where the display panel 01 is located. The first sub-layer 2201 is located on the side of the second sub-layer 2202 facing away from the substrate 10. The main bodies 221 of the first sub-layer 2201 and the second sub-layer 2202 can be made of the same material, such as the aforementioned aluminum.

In the first direction X, the sidewalls of the second sub-layer 2202 protrudes beyond the sidewalls of the first sub-layer 2201.

Exemplarily, as shown in FIG. 3, in the first direction X, two opposing sidewalls of the second sub-layer 2202 protrude beyond two opposing sidewalls of the first sub-layer 2201, respectively.

In the embodiments of the present application, the sidewalls of the second sub-layer 2202 protrude beyond the sidewalls of the first sub-layer 2201. Therefore, the sidewalls of the second sub-layer 2202 and the sidewalls of the first sub-layer 2201 are not aligned in a straight line, which allows the second sub-layer 2202 and the first sub-layer 2201 to form a “step-shaped” structure, i.e., the side surfaces of the second layer 22 may form “steps.” Based on this arrangement, the side surfaces of the second layer 22 are relatively flat. When subsequent film layers are manufactured on the first metal wire 20, the subsequent film layers can ascend along the sidewalls of the second sub-layer 2202 to the sidewalls of the first sub-layer 2201, which is conducive to improving the adhesion effect of the subsequent film layers to the side surfaces of the second layer 22, preventing breaking of the subsequent film layers on the side surfaces of the second layer 22, and further improving the film formation quality of the subsequent film layers.

Optionally, as shown in FIG. 3, the second sub-layer 2202 includes a main body 221 and a protective portion 222. Along the first direction X, the protective portion 222 covers at least a part of the sidewall 221A of the main body 221. Based on this arrangement, the sidewalls of the second sub-layer 2202 in the above embodiment may refer to the sidewalls of the protective portion 222 in the second sub-layer 2202.

As shown in FIG. 3, along the first direction X, the sidewalls 221A of the main body 221 in the second sub-layer 2202 may also protrude beyond the sidewalls 221A of the main body 221 in the first sub-layer 2201.

Exemplarily, as shown in FIG. 3, in the first direction X, the protective portion 222 covers all sidewalls 221A of the main body 221 in the second sub-layer 2202.

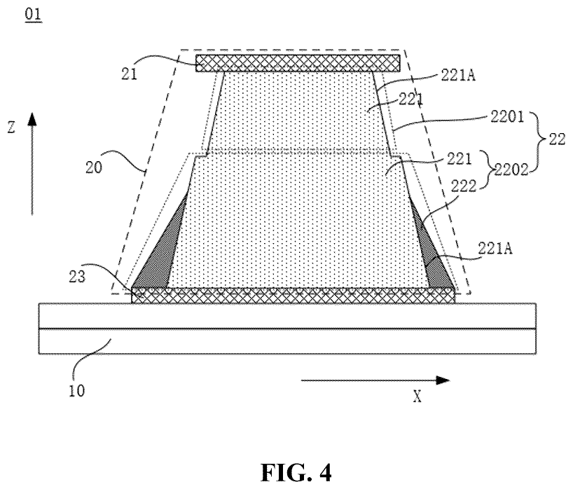

Exemplarily, as shown in FIG. 4, FIG. 4 is a schematic structural diagram of another display panel provided in an embodiment of the present application, in the first direction X, the protective portion 222 covers a part of the sidewalls 221A of the main body 221 in the second sub-layer 2202. In this case, the protective portion 222 covers the sidewalls 221A of the main body 221 in the second sub-layer 2202 that are closest to the substrate 10.

Since the second sub-layer 2202 is closer to the substrate 10 than the first sub-layer 2201, i.e., the second layer 22 has a “narrower at the top and wider at the bottom” structure, providing the second sub-layer 2202 with a protective portion 222 that can protect the sidewall 221A of the main body 221 is conducive to avoiding grooves on the side surfaces of the second sub-layer 2202 that are blocked by the main body 221. When subsequent film layers are manufactured on the first metal wire 20, it is conducive to avoiding the subsequent film layers from breaking on the side surfaces of the second sub-layer 2202.

Optionally, as shown in FIGS. 3 and 4, the first sub-layer 2201 includes the main body 221 but does not include the protective portion 222. That is, the protective portion 222 is not provided outside the main body 221 of the first sub-layer 2201. Based on this arrangement, the sidewalls of the first sub-layer 2201 in the above embodiment can refer to the sidewalls 221A of the main body 221 of the first sub-layer 2201.

Since the sidewalls 221A of the main body 221 of the first sub-layer 2201 are not covered by the protective portion 222, the sidewalls 221A of the main body 221 of the first sub-layer 2201 can be etched so that the sidewalls 221A of the main body 221 of the first sub-layer 2201 are retracted inwardly relative to the sidewalls of the second sub-layer 2202, thereby creating a “stepped” structure on the side surfaces of the second layer 22.

During the manufacturing process of the second layer 22 as shown in FIGS. 3 and 4, the protective portion 222 having uneven thicknesses can be manufactured on the sidewalls 221A of the main body 221 of the second layer 22. The thickness of the protective portion 222 can gradually increase in a direction from the first layer 21 toward the third layer 23.

By flexibly adjusting the thicknesses of the protective portion 222 at different locations, the protection strengths at different locations on the sidewall 221A of the main body 221 can be adjusted, so that the sidewalls of the main body 221 closed to the first layer 21 are less strongly protected and can be etched, while the sidewalls of the main body 221 closed to the third layer 23 are more strongly protected and can be prevented from being etched, which is conducive to achieving relatively great sidewall etching of the first sub-layer 2201, thereby achieving a protrusion of the sidewalls of the second sub-layer 2202 beyond the sidewalls of the first sub-layer 2201 in the first direction X. Furthermore, by controlling the thickness of the protective portion 222, the sidewall etching of the first sub-layer 2201 can be controlled, thereby controlling the degree to which the first sub-layer 2201 is retracted inwardly relative to the second sub-layer 2202.

During the manufacturing process of the second layer 22 shown in FIG. 1, the protective portion 222 on the sidewalls 221A of the main body 221 can be relatively thick, so that all sidewalls 221A of the main body 221 are well protected, which can prevent the sidewalls 221A of the main body 221 from being etched during the subsequent etching process. The thickness of the protective portion 222 can also be gradually increased along the direction from the first layer 21 to the third layer 23, as long as all the sidewalls 221A of the main body 221 are well protected.

Exemplarily, during the manufacturing of the protective portion 222, the central thickness of the protective portion 222 is greater than 20 nm. The central thickness here refers to the thickness of the protective portion 222 at the center of the second layer, along the direction from the first layer 21 to the third layer 23. By flexibly adjusting the thickness of the protective portion 222 closed to the first layer 21, the second layer structure shown in FIG. 1 or 3 can be ultimately achieved.

In an embodiment of the present application, as shown in FIG. 1, the first layer 21 is located at the side of the third layer 23 facing away from the substrate 10. In a first direction X, the third layer 23 protrudes beyond the edge of the first layer 21. That is, the first metal wire 20 can have a “narrower at the top and wider at the bottom” structure.

It is understood that other film layers are typically required to be manufactured on the first metal wire 20. In the embodiments of the present application, by making the third layer 23 on the side closed to the substrate 10 protrude beyond the first layer 21 on the side away from the substrate 10, the side surface of the first metal wire 20 can be relatively smooth, which is conducive to preventing subsequent film layers from breaking on the side surface of the first metal wire 20, thereby improving the film formation quality of subsequent film formation.

Optionally, materials of both the first layer 21 and the third layer 23 comprise titanium. In a direction Z perpendicular to the plane where the display panel 01 is located, the first layer 21 and the third layer 23 are located on opposite sides of the second layer 22. The first layer 21 and the third layer 23 are in contact with other film layers in the display panel 01 and also protect the second layer 22, which is the primary conductive material. Because titanium metal has extremely high chemical stability, both the first layer 21 and the third layer 23 are made of titanium, which is conducive to not only improving the protection of the second layer 22, but also reducing damage to the first metal wires 20 during display panel manufacturing process.

Referring to FIG. 1, in an embodiment of the present application, the first layer 21 is located at the side of the third layer 23 facing away from the substrate 10. In a direction from the first layer 21 to the third layer 23, the thickness D of the protective portion 222 gradually increases along the first direction X.

From the above analysis, it can be seen that in the direction Z perpendicular to the plane where the display panel 01 is located, the first metal wires 20 can have a “narrower at the top and wider at the bottom” structure. That is, the protrusion of the second layer 22 from the first layer 21 can gradually increase in a direction from the first layer 21 to the third layer 23. Furthermore, the protective portion 222 can be formed by injecting gas into the metal material in the second layer 22. Therefore, by injecting gas into the second layer 22 in a direction Z perpendicular to the plane where the display panel 01 is located, the thickness D of the protective portion 222 can be gradually increased, which is conducive to simplifying the manufacturing process for the protective portion 222 and reducing manufacturing difficulty for the protective portion 222.

Furthermore, by gradually increasing the thickness of the protective portion 222, the thicknesses of the protective portion 222 can be flexibly adjusted at different locations, thereby controlling the degree of etching at different locations on the main body 221, which is conducive to the realization of the second layer structure shown in FIGS. 3 and 4.

Optionally, as shown in FIG. 1, the center thickness of the protective portion 222 is d1, where d1 is greater than 20 nm. Here, the center thickness refers to the thickness of the protective portion 222 at the center of the second layer, along the direction from the first layer 21 to the third layer 23. This arrangement is conducive to ensuring the corrosion resistance of the protective portion 222 and reducing the erosion of the main body 221 by corrosive materials from the side surface of the second layer 22, thereby ensuring the structural stability and electrical conductivity of the first metal wire 20.

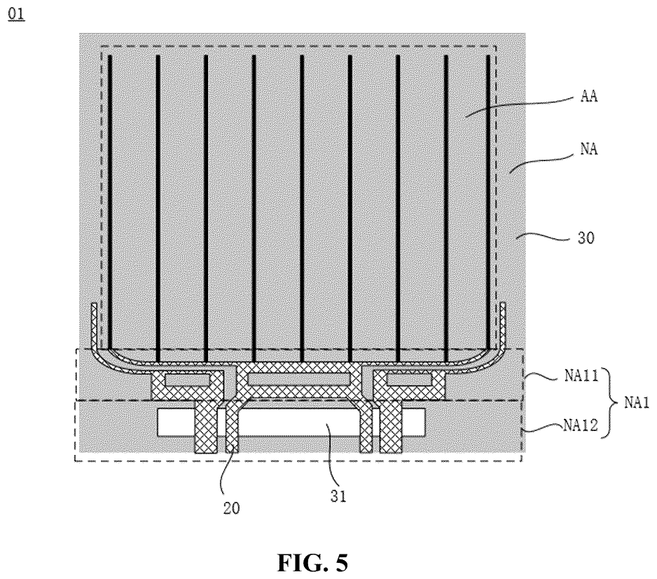

FIG. 5 is a schematic plan view of a display panel provided in an embodiment of the present application.

In an embodiment of the present application, as shown in FIG. 5, the display panel 01 includes a display area AA and a non-display area NA. The non-display area NA surrounds at least a part of the display area AA. The non-display area NA includes a first non-display area NA1 located on one side of the display area AA. The first non-display area NA1 may include a fan-out area NA11 and a bonding area NA12 located on the side of the fan-out area away from the display area AA. The first non-display area NA1 may serve as the “bottom border” of the display panel 01.

The first metal wire 20 is located in the first non-display area NA1.

The inventors of the present application have discovered that the bonding area NA12 can be configured to electrically connect to a driver chip (not shown). The driver chip uses signal traces in the first non-display area NA1 to provide display signals to the display area AA. These signal traces can be directly connected to the pins of the driver chip. Therefore, the conductivity and structural stability of these signal traces are particularly important for transmitting display signals to the display area AA.

In the embodiments of the present application, the first metal wires 20 are located in the first non-display area NA1, so that display signals can be transmitted using the first metal wires 20. As can be seen from the above analysis, the first metal wire 20 can reduce the risk of corrosion and has good conductivity and structural stability, which is conducive to improving the reliability and timeliness of display signal transmission.

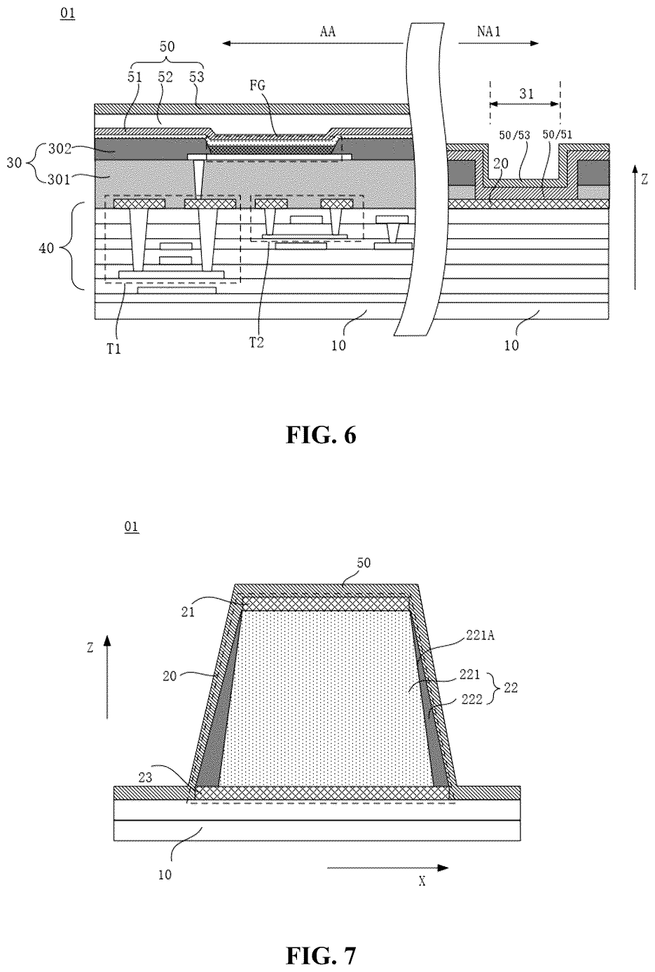

Optionally, referring to FIGS. 5 and 6, FIG. 6 is a schematic structural diagram of the display panel shown in FIG. 5. The display panel 01 also includes an organic layer 30, which is located on the side of the first metal wire 20 away from the substrate 10. The display panel also includes an organic layer clearance area 31, which is located in the first non-display area NA1.

Exemplarily, as shown in FIG. 6, the display panel 01 further includes a transistor array layer 40, which is located on the side of the organic layer 30 closed to the substrate 10. The organic layer 30 may include a planarization layer 301 and a pixel definition layer 302. The light-emitting devices FG can be disposed in the openings of the pixel definition layer 302. The transistor array layer 40 can include both low-temperature polysilicon thin-film transistors T1 and oxide thin-film transistors T2, that is, the display panel 01 can utilize LTPO (low-temperature polycrystalline oxide) technology, so that the advantages of low-temperature polysilicon and oxide can be combined to improve the performance of the display panel 01. No organic layer is disposed in the organic layer clearance area 31. For example, the aforementioned planarization layer 301 and the pixel definition layer 302 are both terminated in this area, and other organic layers located on the substrate are also terminated in this area.

The first metal wire 20 is located on the same layer as the source of the low-temperature polysilicon thin-film transistor T1 and the source of the oxide thin-film transistor T2.

Exemplarily, the first metal wire 20 is a power supply signal line that can be configured to transmit a power supply voltage PVDD or a power supply voltage PVEE.

At least a part of the first metal wire 20 is located in the organic layer clearance area 31. That is, the first metal wire 20 can extend through the organic layer clearance area 31.

As can be seen from the above analysis, the first metal wire 20 can reduce the erosion of the main body 221 by the etching material from the side surface of the second layer 22, which reduces the risk of side etching of the second layer 22, and is conducive to avoiding the formation of grooves on the side surfaces of the first metal wire 20.

Therefore, when the first metal wire 20 extends through the organic layer clearance area 31, it is conducive to preventing organic material from remaining on the side surfaces of the first metal wire 20, preventing the organic material from forming channels for water vapor corrosion along the side surface of the first metal wire 20, and preventing external water and oxygen from invading the interior of the display panel 01 along the side surfaces of the first metal wire 20, thereby improving the reliability and service life of the display panel 01.

Referring again to FIG. 6, the display panel 01 also includes an encapsulation layer 50. The encapsulation layer 50 is located on the side of the first metal wire 20 away from the substrate 10. Along a direction Z perpendicular to the plane where the display panel 01 is located, the encapsulation layer 50 at least partially overlaps the first metal wire 20.

Exemplarily, as shown in FIG. 6, the encapsulation layer 50 includes a first inorganic encapsulation layer 51, an organic encapsulation layer 52, and a second inorganic encapsulation layer 53, which are stacked together. The organic encapsulation layer 52 is disposed between the first inorganic encapsulation layer 51 and the second inorganic encapsulation layer 53. In the embodiments of the present application, the encapsulation layer 50 that overlaps the first metal wire 20 is at least one of the first inorganic encapsulation layer 51 or the second inorganic encapsulation layer 53. Along a direction Z perpendicular to the plane where the display panel 01 is located, the organic encapsulation layer 52 does not overlap the first metal wire 20.

It should be noted that FIG. 6 only illustrates the case where the first inorganic encapsulation layer 51 and the second inorganic encapsulation layer 53 each overlap the first metal wire 20.

Exemplarily, as shown in FIG. 6, the encapsulation layer 50 is in contact with the first metal wire 20 in the organic layer clearance area 31. That is, in the first non-display area NA1, the encapsulation layer 50 is in direct contact with the first metal wire 20.

As shown in conjunction with FIGS. 6 and 7, FIG. 7 is a schematic structural diagram of another display panel provided in an embodiment of the present application. In one implementation of the present application, the protective portion 222 covers the sidewalls 221A of the main body 221 along the first direction X. In this way, the protective portion 222 can completely cover the sidewalls 221A of the main body 221, thereby fully protecting the sidewalls 221A of the main body 221 and preventing deep grooves from forming on the side surfaces of the second layer 22. When the encapsulation layer 50 is manufactured on the first metal wire 20, the encapsulation layer 50 can be relatively tightly encapsulated along the side surface of the second layer 22, thereby achieving a tight encapsulation effect.

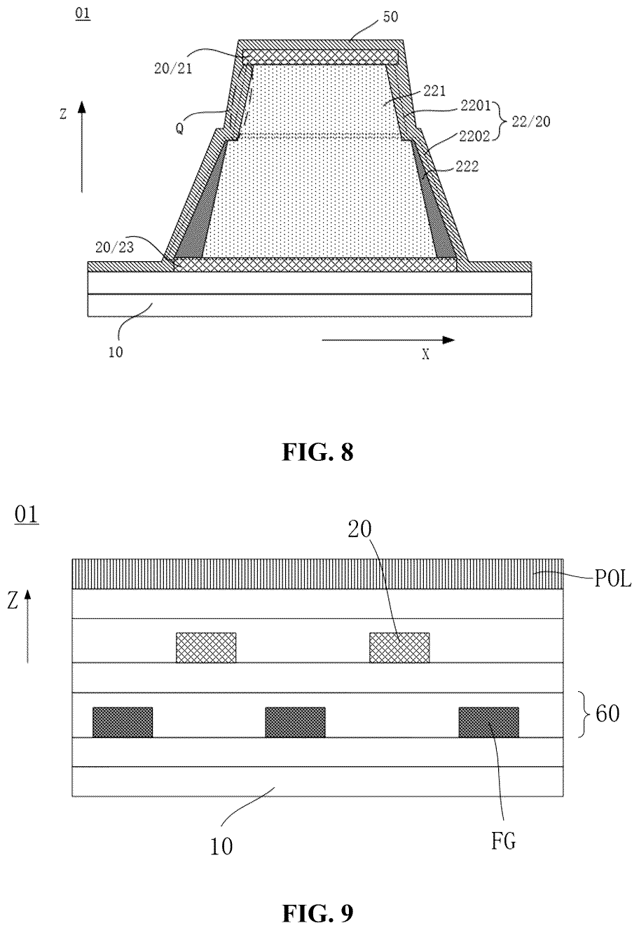

As shown in conjunction with FIGS. 6 and 8, FIG. 8 is a schematic structural diagram of another display panel provided in an embodiment of the present application. In another implementation of the present application, the second layer 22 includes a first sub-layer 2201 and a second sub-layer 2202. The first sub-layer 2201 is located on the side of the second sub-layer 2202 away from the substrate 10. In the first direction X, the second sub-layer 2202 protrudes beyond the first sub-layer 2201, and the side surfaces of the second layer 22 can form a “step” shape. When manufacturing the encapsulation layer 50 on the first metal wire 20, the encapsulation layer 50 can be formed by ascending along the “step-shaped” side surfaces of the second layer 22, further enhancing the encapsulation effect of the encapsulation layer 20.

It should be noted that, as shown in FIG. 8, although the first sub-layer 2201 is retracted inwardly relative to the second sub-layer 2202, because the first sub-layer 2201 is located on the side of the second sub-layer 2201 away from the substrate 10, the gap Q created by this inward retraction is not blocked by the second sub-layer 2201. Moreover, the degree of inward retraction of the first sub-layer 2201 relative to the second sub-layer 2202 is controllable, and the first layer 21 has limited shielding of the gap Q. In the organic layer clearance area 31, the organic material within the gap Q can be reliably removed, which prevents the organic material from forming channels along the side surfaces of the first metal wire 20 for water and oxygen corrosion.

FIG. 9 is a schematic structural diagram of another display panel provided in an embodiment of the present application.

In an embodiment of the present application, as shown in FIG. 9, the display panel 01 further includes a light-emitting layer 60, which includes multiple light-emitting devices FG. First metal wires 20 are located at the side of the light-emitting layer 60 away from the substrate 10.

Optionally, the first metal wires 20 are touch signal lines.

Exemplarily, as shown in FIG. 9, along a direction Z perpendicular to the plane where the display panel 01 is located, the first metal wires 20 do not overlap with the light-emitting devices FG, which prevents the first metal wires 20 from blocking light emitted by the light-emitting devices FG, thereby improving the light efficiency of the light-emitting devices FG.

The inventors of the present application have discovered that, to increase the functional diversity of display panels, display panels often integrate other specific functions, such as touch control, in addition to display functions. To prevent interference between the signals for these specific functions and the display signals, the signal traces required for these specific functions are typically disposed on the side of the light-emitting layer 60 away from the substrate 10. The reliability of these signal traces often determines whether specific functions can be realized.

In view of this, in the embodiments of the present application, the first metal wire 20 is arranged to be located at the side of the light-emitting layer 60 away from the substrate 10, so that the signal configured to achieve a specific function can be transmitted using the first metal wire 20. From the above analysis, it can be seen that the first metal wire 20 can reduce the risk of corrosion and can have good conductivity and structural stability, which is conducive to improving the reliability of the display panel in achieving specific functions.

Any one of the signal traces located at the side of the light-emitting layer 60 facing away from the substrate 10 can be the first metal wire 20.

Referring again to FIG. 9, in an embodiment of the present application, the display panel 01 further includes a polarizer POL located on the side of the first metal wire 20 facing away from the light-emitting layer 60. That is, the polarizer POL is also provided at the side of the light-emitting layer 60 facing away from the substrate 10.

The inventors of the present application have discovered that under high temperature and high humidity conditions, iodine (I₂) in the polarizer POL may precipitate. Iodine reacts with hydroxide ions (OH⁻) to form highly oxidizing iodate ions (IO₃⁻). The chemical reaction formula is: 3I₂+6OH⁻→5I⁻+IO₃⁻+3H₂O. Iodate ions (IO₃⁻) can be converted into iodic acid (HIO₃), which easily corrodes aluminum in nearby metal traces. The chemical reaction formula is: 2Al+HIO₃→Al₂O₃+HI(g).

From the above analysis, it can be seen that the protective portion 222 in the first metal wire 20 is resistant to acid corrosion. Therefore, the first metal wire 20 is disposed to be located between the light-emitting layer 60 and the polarizer POL (any metal trace close to the polarizer POL can be the first metal wire 20), which is conducive to reducing iodic acid corrosion on the main body 221 of the first metal wire 20, thereby ensuring the structural stability of the first metal wire 20.

For example, when the first metal wire 20 is a touch signal line, it can prevent changes in touch capacitance caused by iodic acid corrosion, or even breakage of the touch signal line, thereby ensuring the realization of the touch function of the display panel 01.

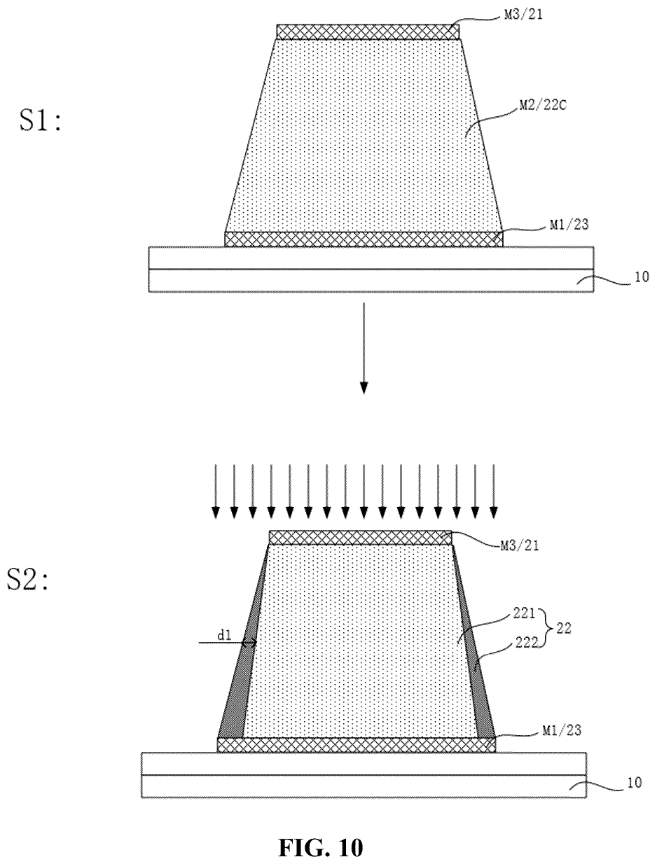

FIG. 10 is a flowchart of a manufacturing process for a display panel provided in an embodiment of the present application.

The embodiments of the present application also provide a method for manufacturing the display panel 01, which is used for manufacturing the display panel 01 described above. The structure of the display panel 01 may be as shown in FIGS. 1-9. As shown in FIG. 10, the manufacturing method includes: Step S1 and Step S2.

In Step S1: a substrate 10 is provided, and a first metal layer M1, a second metal layer M2 and a third metal layer M3 are stacked on one side of the substrate 10 to form the third layer 23, the initial second layer 22C and the first layer 21 of the first metal line 20.

That is, the first metal layer M1 can serve as the third layer 23 of the first metal wire 20, the second metal layer M2 can serve as the initial second layer 22C of the first metal wire 20, and the third metal layer M3 can serve as the first layer 21 of the first metal wire 20.

Optionally, the first metal layer M1 and the third metal layer M3 comprise titanium, and the second metal layer M2 comprises aluminum.

In Step S2: gas is injected into the sidewalls of the initial second layer 22C, and the gas generates a metal compound with the metal in the second metal layer M2 to form the second layer 22.

The metal compound forms the protective portion 222 of the second layer 22, while the metal in the second metal layer M2 that does not react with the gas forms the main body 221 of the second layer 22.

Since the gas reacts with the metal on the sidewalls of the initial second layer 22C to form the metal compound, the protective portion 222 formed by the metal compound can cover at least a part of the sidewalls of the main body 221.

Optionally, in step S2, the center thickness of the metal compound is d1, where d1 is greater than 20 nm. Here, the center thickness refers to the thickness of the metal compound at the center of the second metal layer M2, along the direction from the third metal layer M3 toward the first metal layer M1.

Optionally, the gas is a nitrogen-and/or fluorine-containing gas, such as nitrogen, carbon tetrafluoride, or sulfur hexafluoride.

Exemplarily, since the second metal layer M2 may comprise aluminum, the metal compound may be aluminum nitride or aluminum fluoride.

In the manufacturing method provided in the embodiments of the present application, a protective portion 222 containing a metal compound is provided to cover at least a part of the sidewalls 221A of the main body 221 in the second layer 22. The corrosion-resistant property of the metal compound can be utilized to protect the sidewalls 221A of the main body 221, thereby reducing the erosion of the main body 221 by corrosive materials from the side surfaces of the second layer 22, which is conducive to improving of the structural stability and conductivity of the first metal wire 20.

Furthermore, during the manufacturing process of the second layer 22, the protective portion 222 can be formed by injecting gas into the metal in the second layer 22, which eliminates the need for manufacturing an additional layer of protective material on the side surfaces of the second layer 22, is conducive to simplifying the manufacturing process for the protective portion 222 and reducing the manufacturing cost of the first metal wire 20.

In an embodiment of the present application, as shown in FIGS. 3 and 4, the second layer 22 includes a first sub-layer 2201 and a second sub-layer 2202. The first sub-layer 2201 and the second sub-layer 2202 are connected in a direction Z perpendicular to the plane where the display panel 01 is located. The first sub-layer 2201 is located on the side of the second sub-layer 2202 away from the substrate 10. The main bodies 221 of the first sub-layer 2201 and the second sub-layer 2202 can be made of the same material, such as the aforementioned aluminum. In the first direction X, the sidewalls of the second sub-layer 2202 protrude beyond the sidewalls of the first sub-layer 2201.

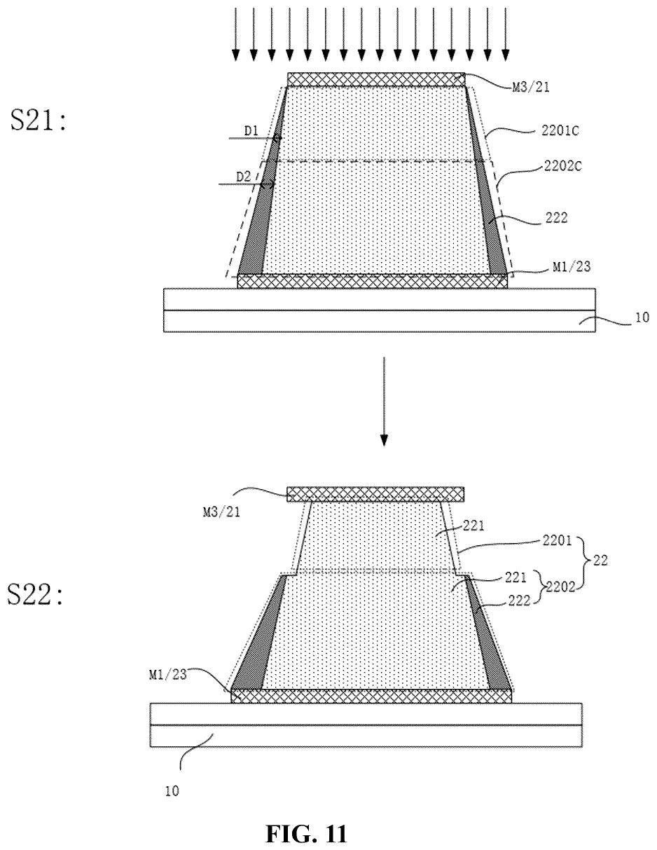

As shown in FIG. 11, FIG. 11 is a flowchart of another process for manufacturing the display panel according to an embodiment of the present application. Before forming the second layer 22, the manufacturing method further includes: Step S21 and Step S22.

In Step S21: along the direction from the first layer 21 to the third layer 23, a gas is injected to react with the metal in the second metal layer M2 to form a metal compound having uneven thicknesses, forming an initial first sub-layer 2201C and an initial second sub-layer 2202C.

The thickness D2 of the metal compound in the initial second sub-layer 2202C is greater than the thickness D1 of the metal compound in the initial first sub-layer 2201C. The minimum thickness of the metal compound in the initial second sub-layer 2202C may be greater than the maximum thickness of the metal compound in the initial first sub-layer 2201C. Here, the thickness of the metal compound refers to the thickness in the first direction X.

Optionally, the thickness of the metal compound gradually increases along the direction from the first layer 21 to the third layer 23. In step S21, the center thickness of the metal compound may be greater than 20 nm. Here, the center thickness refers to the thickness of the metal compound at the center of the second metal layer M2 along the direction from the first layer 21 to the third layer 23.

In Step S22: the initial first sub-layer 2201C and the initial second sub-layer 2202C are etched to form the first sub-layer 2201 and the second sub-layer 2202.

In step S22, due to the relatively large thickness of the metal compound in the initial second sub-layer 2202C, the metal in the initial second sub-layer 2202C is well protected by the metal compound. However, the thickness of metal compound in the initial first sub-layer 2201C is relatively thin, so that a small amount of metal in the initial first sub-layer 2201C is etched, which results in the second sub-layer 2202 protruding beyond the first sub-layer 2201 in the first direction X.

In the embodiments of the present application, only a small amount of metal in the initial first sub-layer 2201C is etched, which can also reduce the etching amount of metal in the second layer 22 and improve the structural stability and conductivity of the first metal wire 20.

Furthermore, the sidewalls of the second sub-layer 2202 and the sidewalls of the first sub-layer 2201 are not aligned, and the second sub-layer 2202 and the first sub-layer 2201 can form a “step-shaped” structure, that is, the side surfaces of the second layer 22 can form “steps.” Based on this arrangement, the side surfaces of the second layer 22 are relatively flat. When subsequent film layers are manufactured on the first metal wire 20, the subsequent film layers can ascend along the sidewalls of the second sub-layer 2202 to the sidewalls of the first sub-layer 2201, which is conducive to improving the adhesion effect of the subsequent film layers to the side surfaces of the second layer 22, thereby further improving the film formation quality of the subsequent film layers.

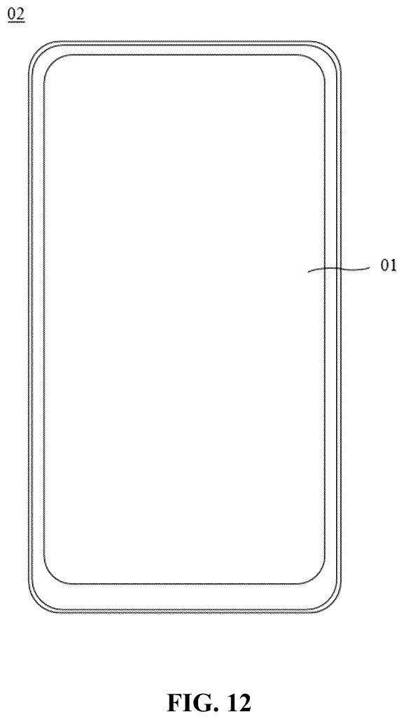

FIG. 12 is a schematic diagram of a display apparatus provided in an embodiment of the present application.

The embodiments of the present application also provide a display apparatus 02, as shown in FIG. 12. The display apparatus 02 includes the display panel 01 provided in the above-described embodiments. The display apparatus 02 provided in the embodiments of the present application can be a mobile phone as shown in FIG. 12, or can be an electronic apparatus such as a computer, television, or car display, which is not limited in the present application.

In the display apparatus 02, a protective portion 222 containing a metal compound is provided, covering at least a part of the sidewalls 221A of the main body 221 in the second layer 22, which utilizes the corrosion-resistant property of the metal compound to protect the sidewalls 221A of the main body 221, reducing the erosion of the main body 221 by corrosive materials from the side surfaces of the second layer 22, thereby improving the structural stability and electrical conductivity of the first metal wire 20.

Furthermore, during the manufacturing process of the second layer 22, the protective portion 222 can be formed by injecting gas into the metal in the second layer 22, which eliminates the need for manufacturing an additional layer of protective material on the side surfaces of the second layer 22, is conducive to simplifying the manufacturing process for the protective portion 222 and reducing the cost of manufacturing the first metal wire 20.

The foregoing descriptions are merely preferred embodiments of the present application and are not intended to limit the present application. Any modifications, equivalent substitutions, or improvements made within the gist and principles of the present application should be included within the scope of protection in the present application.

What is claimed is:

1. A display panel, comprising
a substrate; and
a first metal wire located on a side of the substrate, the first metal wire comprising a first layer, a second layer, and a third layer that are stacked, the second layer being located between the first layer and the third layer,
wherein the second layer comprising a main body and a protective portion, the protective portion comprising a metal compound and covering at least a part of sidewalls of the main body along a first direction that is parallel to a plane where the display panel is located and extends from the main body toward the protective portion.

2. The display panel according to claim 1, wherein the protective portion comprises at least one of a metal nitride or a metal fluoride.

3. The display panel according to claim 2, wherein the main body comprises aluminum, and the protective portion comprises at least one of aluminum nitride or aluminum fluoride.

4. The display panel according to claim 1, wherein the protective portion is located outside the main body and in contact with the sidewalls of the main body.

5. The display panel according to claim 4, wherein the protective portion covers the sidewalls of the main body along the first direction.

6. The display panel according to claim 1, wherein the second layer comprises a first sub-layer and a second sub-layer, the first sub-layer and the second sub-layer being connected in a direction perpendicular to the plane where the display panel is located, and the first sub-layer being located on a side of the second sub-layer away from the substrate;
in the first direction, sidewalls of the second sub-layer protrude beyond sidewalls of the first sub-layer.

7. The display panel according to claim 6, wherein the second sub-layer comprises the main body and the protective portion, and along the first direction, the protective portion covers at least a part of the sidewalls of the main body.

8. The display panel according to claim 7, wherein the first sub-layer comprises the main body and does not comprise the protective portion.

9. The display panel according to claim 1, wherein materials of both the first layer and the third layer comprise titanium.

10. The display panel according to claim 1, wherein the first layer is located at a side of the third layer away from the substrate, and in the first direction, the third layer protrudes beyond an edge of the first layer.

11. The display panel according to claim 1, wherein the first layer is located at a side of the third layer away from the substrate, and a thickness of the protective portion gradually increases along the first direction from the first layer to the third layer.

12. The display panel according to claim 1, wherein
the display panel comprises a display area and a non-display area, the non-display area surrounding at least a part of the display area;
the non-display area comprises a first non-display area located at a side of the display area; and
the first metal wire is located in the first non-display area.

13. The display panel according to claim 12, wherein the first non-display area comprises an organic layer clearance area and at least a part of the first metal wire is located in the organic layer clearance area.

14. The display panel according to claim 12, further comprising an encapsulation layer, wherein the encapsulation layer is located on a side of the first metal wire away from the substrate and at least partially overlaps the first metal wire in a direction perpendicular to the plane where the display panel is located.

15. The display panel according to claim 12, wherein the first metal wire is a power supply signal line.

16. The display panel according to claim 1, further comprising a light-emitting layer, wherein the first metal wire is located at a side of the light-emitting layer away from the substrate.

17. The display panel according to claim 16, further comprising a polarizer located at a side of the first metal wire away from the light-emitting layer.

18. The display panel according to claim 16, wherein the first metal wire is a touch signal line.

19. A method for manufacturing the display panel, configured to manufacture the display panel according to claim 1, the method comprising:
providing the substrate;
stacking and manufacturing a first metal layer, a second metal layer, and a third metal layer on the side of the substrate to form the third layer, an initial second layer, and the first layer of the first metal wire, respectively; and
injecting a gas into sidewalls of the initial second layer, so that the gas reacts with a metal in the second metal layer to form a metal compound to form the second layer.

20. A display apparatus, comprising a display panel comprising a substrate and a first metal wire located on a side of the substrate, the first metal wire comprising a first layer, a second layer, and a third layer that are stacked, the second layer being located between the first layer and the third layer;
the second layer comprising a main body and a protective portion, the protective portion comprising a metal compound and covering at least a part of sidewalls of the main body along a first direction,
wherein the first direction is parallel to a plane where the display panel is located and extends from the main body toward the protective portion.
